(19) United States
(12) Patent Application Publication
(10) Pub. No.: US 2025/0377674 A1
(43) Pub. Date: Dec. 11, 2025

(54) HEAT TRANSFER FLUID SUPPLY SYSTEM

(71) Applicant: SEMICS INC., Gwangju-si (KR)

(72) Inventor: Ho Hyeon MOON, Anyang-si (KR)

(21) Appl. No.: 18/850,436

(22) PCT Filed: Jan. 19, 2024
(86) PCT No.: PCT/KR2024/000980

§ 371 Date: Mar. 28, 2025

(30) Foreign Application Priority Data
Feb. 7, 2023 (KR) 10-2023-0016019

(51) Int. Cl. G05D 16/20; F28F 27/00; G05D 23/19

(52) U.S. Cl. CPC G05D 16/2066; F28F 27/00; G05D 23/19

(57) ABSTRACT

A system for supplying heat transfer fluid is provided. The heat transfer fluid supply system according to an aspect of the present disclosure may include: a body to-be-cooled having a heat transfer flow path through which a heat transfer fluid passes therein; a tank in which the heat transfer fluid is stored, wherein the heat transfer fluid is stored in a space formed inside the tank; a supply flow path connecting one side of the heat transfer flow path and the tank; a return flow path connecting the other side of the heat transfer flow path and the tank; and a controller that controls an inner pressure of the tank.

### TECHNICAL FIELD

The present disclosure relates to a system for supplying heat transfer fluid (hereinafter, referred to as a “heat transfer fluid supply system”), and more particularly, to a heat transfer fluid supply system capable of controlling the pressure of the heat transfer fluid.

### BACKGROUND ART

As the necessary temperature range for inspecting semiconductor devices is widened, the inspection environment provided by equipment for inspecting semiconductor devices has become diversified.

In particular, in order to control the temperature of the prober chuck supporting semiconductor devices, it is increasingly required to use or exceed the limit of the temperature range of the heat transfer fluid supplied to the prober chuck.

In this case, when the heat transfer fluid for controlling the temperature of the prober chuck is used at low temperatures, it is advantageous to use heat transfer fluids with low viscosity in consideration of heat exchange performance, limiting pressure of the pipe, and pump, and the like.

However, in the case of heat transfer fluids with low viscosity, there is a problem in that the vaporization point is low, so that the formation of fluid flow may be limited.

In addition, there is a problem that the heat transfer fluid, which is generally usable at a high temperature, has a high viscosity such that its use is limited in a semiconductor device inspection apparatus at a low temperature due to physical characteristics. Accordingly, the temperature of heat transfer fluid entering the prober chuck is generally set to be lower than the temperature of the prober chuck and supplied.

However, as the difference between the temperature of the heat transfer fluid and the set temperature of the probe chuck increases, the heater that heats the probe chuck requires high power for temperature compensation, adversely affects the temperature uniformity of the probe chuck, and the yield drops when inspecting the semiconductor device.

### DISCLOSURE

### Technical Problem

The present disclosure is to solve the above problems, and it is an object of the present disclosure to provide a heat transfer fluid supply system that can be used by increasing a vaporization point of a heat transfer fluid with a low viscosity at a low temperature.

The technical problems of the present disclosure are not limited to the above-mentioned technical problems, and other technical problems not mentioned herein can be clearly understood by those skilled in the art from the following description.

### Technical Solution

In order to solve the above problem, a heat transfer fluid supply system according to one aspect of the present disclosure may include: a body to-be-cooled having a heat transfer flow path through which a heat transfer fluid passes therein; a tank in which the heat transfer fluid is stored, wherein the heat transfer fluid is stored in a space formed inside the tank; a supply flow path connecting one side of the heat transfer flow path and the tank; a return flow path connecting the other side of the heat transfer flow path and the tank; and a controller that controls an inner pressure of the tank.

In this case, the heat transfer fluid supply system may further include a pressurizing pump supplying dry air to the tank, wherein the controller is configured to add a predetermined pressure to the inner pressure of the tank using the pressurizing pump.

In this case, the heat transfer fluid supply system may further include a pressurizing pump valve provided in the tank to allow the inner space of the tank and the pressurizing pump to communicate with each other.

In this case, the controller may control the inner pressure of the tank by controlling an opening and closing of the pressurizing pump valve.

In this case, the pressurizing pump may constantly provide the predetermined pressure.

In this case, a position where the pressurizing pump is connected to the tank may be located above a water level of the heat transfer fluid stored in the tank.

In this case, the predetermined pressure may be 0.4 bar or more and 0.6 bar or less.

In this case, the heat transfer fluid supply system may further include a body to-be-cooled heater for heating the body to-be-cooled, wherein the controller controls a temperature of the body to-be-cooled using the heat transfer fluid and the body to-be-cooled heater.

In this case, the heat transfer fluid supply system may further include a pressure regulating valve provided in the tank to allow the inner space of the tank and the outside of the tank to communicate with each other.

In this case, the controller may control the inner pressure of the tank by controlling an opening and closing of the pressure regulating valve.

In this case, the controller may control the inner pressure added to the tank by thermal expansion of the heat transfer fluid passing through the body to-be-cooled.

In this case, the heat transfer fluid supply system may further include a pressure sensor provided in the tank to measure the inner pressure of the tank, wherein the controller controls the inner pressure of the tank by controlling the opening and closing of the pressure regulating valve through pressure information measured using the pressure sensor.

In this case, the heat transfer fluid supply system may further include a temperature sensor provided in the tank to measure a temperature of the heat transfer fluid stored in the tank, wherein the controller controls the inner pressure of the tank by controlling the opening and closing of the pressure regulating valve through temperature information measured using the temperature sensor.

In this case, the heat transfer fluid supply system may further include a pressurizing pump supplying dry air to constantly provide a predetermined pressure to the tank, and a pressurizing pump valve provided in the tank to allow the inner space of the tank and the pressurizing pump to communicate with each other, wherein the controller controls the inner pressure of the tank by further controlling the opening and closing of the pressurizing pump valve.

In this case, the controller may close the pressurizing pump valve and opens the pressure regulating valve when the temperature information measured using the temperature sensor is less than a first temperature.

In this case, the controller may open the pressurizing pump valve and closes the pressure regulating valve when the temperature information measured using the temperature sensor is equal to or higher than the first temperature such that the inner pressure of the tank gradually increases by thermal expansion of the heat transfer fluid passing through the body to-be-cooled.

In this case, the controller may open the pressurizing pump valve when the temperature information measured using the temperature sensor is greater than or equal to a second temperature that is higher than the first temperature.

In this case, the heat transfer fluid supply system may further include a pneumatic regulator that constantly maintains the inner pressure of the tank in a state in which the inside of the tank is pressurized using the pressurizing pump.

In this case, a position where the supply flow path may be connected to the tank is located below the water level of the heat transfer fluid stored inside the tank, and a position where the return flow path may be connected to the tank is located below the water level of the heat transfer fluid stored inside the tank.

In this case, the heat transfer fluid supply system may further include a pump connected to the supply flow path or the return flow path to generate a fluid flow such that the heat transfer fluid stored inside the tank returns to the tank via the supply flow path, the body to-be-cooled, and the return flow path in that order; and
a temperature regulator maintaining the temperature of the heat transfer fluid provided to the body to-be-cooled at a predetermined temperature.

### Advantageous Effects

The heat transfer fluid supply system according to an embodiment of the present disclosure can be used by increasing the vaporization point of the heat transfer fluid with the low viscosity at the low temperature by pressurizing the heat transfer fluid through the pressurizing pump.

In addition, the heat transfer fluid supply system according to an embodiment of the present disclosure can be used by increasing the vaporization point of the heat transfer fluid with the low viscosity at the low temperature by increasing the inside pressure of the tank by thermal expansion of the heat transfer fluid via the body to-be-cooled.

It should be understood that the effects of the present disclosure are not limited to the above effects and include all effects that can be inferred from the description of the present disclosure or the configuration of the invention described in the claims.

### DESCRIPTION OF DRAWINGS

FIG. 1 is a diagram schematically showing a heat transfer fluid supply system according to an embodiment of the present disclosure.

FIG. 2 is a block diagram showing a controller of a heat transfer fluid supply system according to an embodiment of the present disclosure.

FIG. 3 is a diagram showing one water level of the tank of a heat transfer fluid supply system according to an embodiment of the present disclosure.

FIG. 4 is a diagram showing the other water level of a tank of a heat transfer fluid supply system according to an embodiment of the present disclosure.

FIG. 5 is a graph showing viscosity according to temperature of the heat transfer fluid used in the heat transfer fluid supply system according to an embodiment of the present disclosure.

FIG. 6 is a graph showing pressure according to vaporization point of the heat transfer fluid used in the heat transfer fluid supply system according to an embodiment of the present disclosure.

FIG. 7 is a graph showing pressure over time of the heat transfer fluid used in the conventional heat transfer fluid supply system.

FIG. 8 is a graph showing pressure over time of the heat transfer fluid used in the heat transfer fluid supply system according to an embodiment of the present disclosure.

### MODES OF THE INVENTION

Hereinafter, embodiments of the present disclosure will be described in detail with reference to the accompanying drawings so that those skilled in the art can easily implement them. The present disclosure may be implemented in various different forms and is not limited to the embodiments described herein. In order to clearly explain the present disclosure, parts irrelevant to the description are omitted in the drawings, and the same or similar components are denoted by the same reference numerals throughout the entire specification.

The words and terms used in this specification and the claims are not interpreted as limited to ordinary or dictionary meanings but should be interpreted as meanings and concepts consistent with the technical idea of the present disclosure according to the principle in which the inventor can define the terms and concepts in order to best explain their invention.

Therefore, the embodiments and structures shown in the drawings described herein correspond to preferred embodiments of the present disclosure and do not all represent the technical idea of the present disclosure, so the corresponding structures may be various equivalents and modifications to replace them at the time of filing the present disclosure.

In this specification, the terms “include” or “comprise” and the like are intended to describe the presence of features, numbers, steps, operations, components, parts or combinations thereof described in the specification, and should not be construed as excluding the presence or addition of one or more other features, numbers, steps, operations, components, parts or combinations thereof.

It is noted that a component is in the “front”, “rear”, “upper” or “lower” of another component, unless otherwise specified, not only that it is disposed in the “front”, “rear”, “upper” or “lower” immediately adjacent to the other component, but also that another component is disposed in the middle. In addition, the fact that a component is “connected” to another component includes not only directly connected to each other but also indirectly connected to each other unless otherwise specified.

Hereinafter, a heat transfer fluid supply system according to various embodiments of the present disclosure will be described with reference to the drawings.

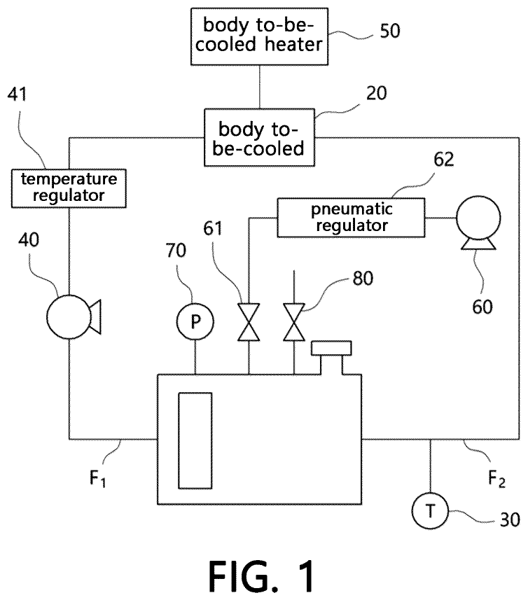

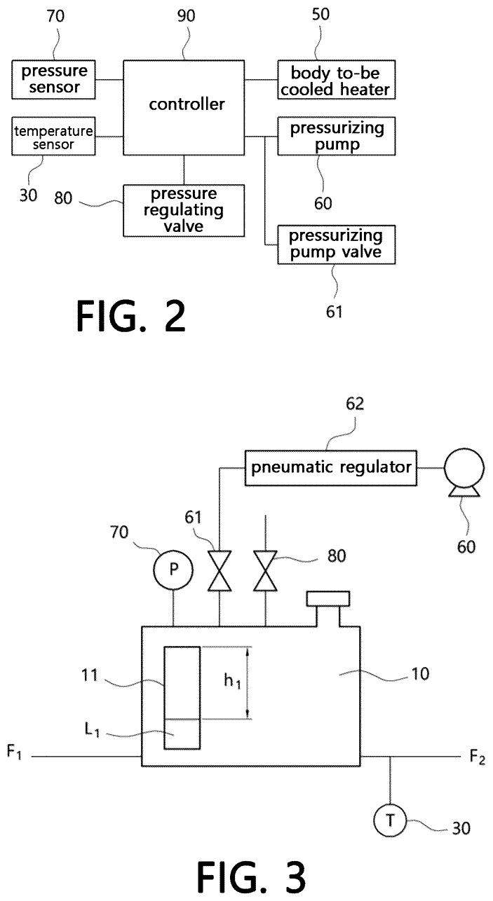

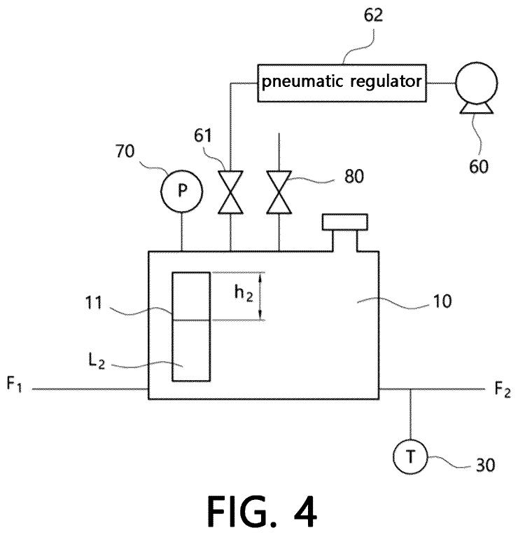

FIG. 1 is a diagram schematically showing a heat transfer fluid supply system according to an embodiment of the present disclosure. FIG. 2 is a block diagram showing a controller of a heat transfer fluid supply system according to an embodiment of the present disclosure. FIG. 3 is a diagram showing a first water level of a tank of a heat transfer fluid supply system according to an embodiment of the present disclosure. FIG. 4 is a diagram showing a second water level of a tank of a heat transfer fluid supply system according to an embodiment of the present disclosure.

In this case, FIGS. 1, 3, and 4 are schematic illustrations of one embodiment of the present disclosure, and configuration shown in FIGS. 1, 3, and 4 does not have to be the same shape as shown in FIGS. 1, 3, and 4, or should not be disposed at a location.

As shown in FIG. 1, the heat transfer fluid supply system 1 according to an embodiment of the present disclosure includes a tank 10, a body to-be-cooled 20, a pump 40, a body to-be-cooled heater 50, a pressurizing pump 60, a pressure sensor 70, a pressure regulating valve 80, and a controller 90.

The heat transfer fluid supply system 1 is a system that supplies heat transfer fluid for transferring or receiving heat to a specific location within the equipment. There is no limitation on the devices in which the heat transfer fluid supply system 1 may be installed. For example, it may be provided in test equipment for inspecting semiconductor devices to supply heat transfer fluid.

Hereinafter, the heat transfer fluid supply system 1 will be described as a heat transfer fluid supply system 1 provided in test equipment to supply heat transfer fluid to a probe chuck supporting a semiconductor device among various types of equipment. In other words, in this embodiment, an object to-be-cooled or to-be-heated through the heat transfer fluid, that is, a body to-be-cooled 20 is explained as the prober chuck.

In this case, the heat transfer fluid refers to a liquid that indirectly cools or heats the object to-be-cooled or heated through a heat exchanger or the like.

Various materials known in the art may be used as a material that may be used as a heat transfer fluid. However, it is preferable that the heat transfer fluid used for the effect of the present disclosure has a low viscosity at a low temperature. For example, HT135, HT170, HFE7500 and HFE7200 may be used as heat transfer fluids.

The tank 10 has a space formed therein. The shape of the tank 10 is not limited as long as a space may be formed therein. At this time, heat transfer fluid is stored in the inner space of the tank 10.

The heat transfer fluid is stored inside the tank 10 in a non-filled manner. That is, heat transfer fluid is located on the lower side of the inside of the tank 10 by density, and a space is formed above the heat transfer fluid.

Meanwhile, it is preferable that the tank 10 be formed to extend in a vertical direction. That is, it is preferable that the cross-sectional area perpendicular to the vertical direction of the tank 10 be uniformly formed. In this case, the volume of the heat transfer fluid stored inside the tank 10 is proportional to the height of the heat transfer fluid. In this embodiment, it is described that the tank 10 extends in the up and down directions.

At this time, as shown in FIGS. 3 and 4, a transparent window 11 that can visually identify the volume of heat transfer fluid stored in the tank 10 may be formed by extending in the vertical direction, which is the extension direction of the tank 10. This allows the user to visually determine whether the heat transfer fluid is expanded or compressed.

The inner space of the tank 10 is connected to the body to-be-cooled 20. In this case, a heat transfer flow path is formed inside the body to-be-cooled 20 for heat exchange. Through this, in the process of inspecting the semiconductor device, the heat transfer fluid may absorb the heat of the body to-be-cooled 20 while passing through the heat transfer flow path of the body to-be-cooled 20.

As shown in FIG. 1, a supply flow path L1 connects one side of the tank 10 and one side of the heat transfer flow path of the body to-be-cooled 20 and a return flow path L2 connects the other side of the tank 10 and the other side of the body to-be-cooled 20 so that the inner space of the tank 10 and the heat transfer flow path of the body to-be-cooled 20 may be connected.

The supply flow path L1 and the return flow path L2 are not limited to the shape or the material used to form the passage when the heat transfer fluid may reciprocate between the tank 10 and the body to-be-cooled 20.

As shown in FIG. 1, a pump 40 is connected to the supply flow path L1 or the return flow path L2. In this embodiment, it is explained that the pump 40 is connected to the supply flow path L1.

The pump 40 forms a flow of fluid such that the heat transfer fluid stored in the tank 10 returns to the tank 10 via the supply flow path 11, the body to-be-cooled 20, and the return flow path 12 in that order.

A temperature regulator 41 is installed between the pump 40 and the body to-be-cooled 20. The temperature regulator 41 maintains a temperature of the heat transfer fluid provided to the body to-be-cooled 20 at a predetermined temperature. That is, the temperature regulator 41 may be a heater when the temperature of the heat transfer fluid is lower than the predetermined temperature and may be a cooler when the temperature of the heat transfer fluid is higher than the predetermined temperature. The temperature regulator 41 may use various known devices when the temperature of the heat transfer fluid may be increased or decreased.

In this case, a position where the supply flow path 11 and the return flow path 12 are connected to the tank 10 is located below the water level of the heat transfer fluid stored in the tank 10. Accordingly, the heat transfer fluid is allowed to circulate continuously while the heat transfer fluid is circulated by the pump 40.

In particular, since the supply flow path 11 and the return flow path 12 are connected to the tank 10 to be located below the water level of the heat transfer fluid, even if the inner pressure of the tank 10 is adjusted through the controller 90 to be described later, the same pressure may be maintained in the passage along which the heat transfer fluid moves.

The controller 90 controls the inner pressure of the tank 10. Through this, it is possible to increase the pressure of the heat transfer fluid stored in the tank 10, thereby increasing a vaporization point of the heat transfer fluid, thereby preventing the problem of being vaporized and not continuously transferring heat through the heat transfer fluid even if the heat transfer fluid has a low viscosity at a low temperature. In addition, it is also possible to prevent cavitation due to the low pressure near the pump 40.

As shown in FIG. 1, the body to-be-cooled heater 50 is connected to the body to-be-cooled 20. In addition, as shown in FIG. 2, the body to-be-cooled heater 50 is controlled by the controller 90. The body to-be-cooled heater 50 heats the body to-be-cooled 20.

In this case, the controller 90 controls the pump 40 to circulate the heat transfer fluid to the body to-be-cooled 20 and controls the body to-be-cooled 20 to maintain an appropriate temperature. When the body to-be-cooled heater 50 is provided, the heat transfer fluid is used to cool the body to-be-cooled 20 so as not to be excessively heated.

In this case, the temperature of the heat transfer fluid passing through the body to-be-cooled 20 increases due to the heat absorbed from the body to-be-cooled 20. Accordingly, the heat transfer fluid thermally expands, the inner pressure of the tank 10 increases, and the total pressure of the circulating heat transfer fluid increases.

In detail, as shown in FIG. 3, a space is formed at an upper side of the tank 10 before the heat transfer fluid stored in the tank 10 passes through the body to-be-cooled 20. At this time, since the inside volume of the tank 10 is proportional to the height, the upper space of the tank 10 may be expressed as the height h1.

When the controller 90 heats the body to-be-cooled 20 through the body to-be-cooled heater 50, the temperature of the heat transfer fluid passing through the body to-be-cooled 20 increases, and the heat transfer fluid thermally expands. That is, as shown in FIG. 4, the inside volume of the heat transfer fluid increases, and the height of the upper space inside the tank 10 decreases as h2.

Meanwhile, as shown in FIG. 1, a pressure sensor 70 is installed in the tank 10. The pressure sensor 70 may measure the inner pressure of the tank 10. It is preferable that the pressure measured by the pressure sensor 70 measures the atmospheric pressure of the space above the heat transfer fluid inside the tank 10. However, the pressure of the heat transfer fluid may be directly measured, without being limited thereto. In this case, the controller 90 may receive the pressure information measured by the pressure sensor 70.

As shown in FIG. 1, the pressure regulating valve 80 is installed in the tank 10. The pressure regulating valve 80 is provided on the upper side of the tank 10 to allow the inner space of the tank 10 and the outside of the tank 10 to communicate with each other. In this case, when the pressure regulating valve 80 is opened, the air located at the upper side of the inside of the tank 10 may exit to the outside or the outside air may enter the inside of the tank 10.

The pressure regulating valve 80 may be a solenoid valve connected to the controller 90 and electronically controlled to open and close by the controller 90. When the pressure measured by the pressure sensor 70 exceeds a predetermined pressure, the controller 90 may open the pressure regulating valve 80 to lower the inner pressure of the tank 10 and adjust the inner pressure of the tank 10 to an appropriate pressure.

In particular, the controller 90 may control the inner pressure of the tank 10, which is caused by the expansion of the heat transfer fluid as the temperature of the heat transfer fluid passing through the body to-be-cooled 20 increases, to a predetermined pressure by controlling the opening and closing degree and the opening and closing time of the pressure regulating valve 80.

However, the reference by which the controller 90 controls the pressure regulating valve 80 is not determined only by the pressure collected from the pressure sensor 70. A detailed description of this will be provided later along with a description of the temperature sensor 30.

Meanwhile, as shown in FIG. 2, the pressurizing pump 60 connected to the tank 10 is connected to the controller 90. The controller 90 may supply dry air to the inside of the tank 10 through the pressurizing pump 60.

The controller 90 may control the pressurizing pump 60 to adjust the amount of dry air provided to the inside of the tank 10. The controller 90 may use a method of controlling the output of the pressurizing pump 60 itself or may use a pressurizing pump valve 61 described later.

It is preferable that a position where the pressurizing pump 60 is connected to the tank 10 is located above the water level of the heat transfer fluid stored in the tank 10. Through this, even if dry air is introduced into the inside of the tank 10, bubbles do not form inside the heat transfer fluid or interfere with the flow of the heat transfer fluid.

As shown in FIG. 1, the pressurizing pump 60 may be connected to the tank 10 through the pressurizing pump valve 61. The pressurizing pump valve 61 opens and closes the flow path connecting the pressurizing pump 60 and the tank 10.

The pressurizing pump valve 61 may use various known valves. In this embodiment, it will be described as a solenoid valve that is connected to the controller 90 and can electronically control opening and closing.

The controller 90 may control the amount of dry air provided by the pressurizing pump 60 to the tank 10 by adjusting the opening and closing degree and time of the pressurizing pump valve 61. That is, the controller 90 may adjust the inner pressure of the tank 10 through the pressurizing pump valve 61.

At this time, the pressurizing pump 60 is preferably a pump that provides dry air at a constant pressure. This is because the pressure pump 60 must provide a constant pressure so that the controller 90 may control the inner pressure of the tank 10 by controlling the pressure pump valve 61.

In particular, the pressurizing pump 60 providing dry air at a constant pressure may be a pneumatic facility provided inside a factory in which the heat transfer fluid supply system 1 according to an embodiment of the present disclosure is installed. In other words, the tank 10 is connected to pneumatic equipment provided in most factories, so that dry air that may be supplied to the inside of the tank 10 may be easily supplied.

The controller 90 may add a predetermined pressure to the inner pressure of the tank 10 through the pressurizing pump 60. In more detail, as shown in FIG. 4, even before the dry air is supplied by the pressurizing pump 60 inside the tank 10, a predetermined space is formed in the upper side of the tank 10. At this time, since the inside volume of the tank 10 is proportional to the height, the upper space of the tank 10 may be expressed as h2.

By driving the pressurizing pump 60 or opening the pressurizing pump valve 61 connected to the pressurizing pump 60, the controller 90 pressurizes the heat transfer fluid as the dry air is supplied to the inside of the tank 10. That is, as the volume of the heat transfer fluid decreases, as shown in FIG. 3, the size of the upper space inside the tank 10 increases to h1.

To sum up the above, the controller 90 uses the pressure regulating valve 80 or the pressurizing pump 60 or uses the pressure regulating valve 80 and the pressurizing pump 60 together to adjust the pressure of the heat transfer fluid. In this case, the pressure added by the controller 90 pressurizing the heat transfer fluid may be 0.4 bar or more and 0.6 bar or less, and preferably 0.5 bar.

Meanwhile, as shown in FIG. 1, the heat transfer fluid supply system 1 according to an embodiment of the present disclosure may further include a temperature sensor 30 provided in the tank 10.

The temperature sensor 30 measures the temperature of the heat transfer fluid introduced into the tank 10. The temperature sensor 30 may use various known temperature sensors as long as they may measure the temperature of the fluid. There are no restrictions on how or where the temperature sensor 30 is installed in the tank 10.

The temperature sensor 30 absorbs heat from the body to-be-cooled 20 while passing through the body to-be-cooled 20 to measure the temperature of the heat transfer fluid, which has increased. That is, the heat transfer fluid whose temperature the temperature sensor 30 measures is not a heat transfer fluid controlled to a predetermined temperature in order to move to the body to-be-cooled 20.

The controller 90 may control the inner pressure of the tank 10 through temperature information of the heat transfer fluid measured by the temperature sensor 30. Hereinafter, a method in which the controller 90 controls the inner pressure of the tank 10 using the pressure pump valve 61 and the pressure control valve 80 together based on the temperature information of the heat transfer fluid will be described. At this time, the pressurizing pump 60 is a pressurizing pump 60 that provides dry air at a constant pressure, and as described above, it is a pressurizing pump 60 that can control the amount of dry air provided using the pressurizing pump valve 61.

However, the following description is to describe any one example of the operation of the controller 90 that controls the inner pressure of the tank 10 by using the pressurizing pump valve 61 and the pressure regulating valve 80 together, and the heat transfer fluid supply system 1 according to an embodiment of the present disclosure does not necessarily operate in the following manner. The controller 90 may control the pressure pump valve 61 and the pressure regulating valve 80 according to the temperature range based on the first temperature and the second temperature higher than the first temperature, as measured by the temperature sensor 30.

In this case, the first temperature and the second temperature may be set differently depending on the type of heat transfer fluid. For example, when the heat transfer fluid is HFE7500, it is preferable to set the first temperature to 60 degrees Celsius and the second temperature to 100 degrees Celsius.

When the temperature information measured through the temperature sensor 30 is less than the first temperature, the controller 90 closes the pressurizing pump valve 61 and opens the pressure regulating valve. Accordingly, the inner space of the tank 10 is capable of fluid communication with the outside, and the inner pressure of the tank 10 is maintained at one atmosphere.

That is, the inside pressure of the tank 10 is maintained at one atmosphere even if there is thermal expansion due to the temperature of the heat transfer fluid, and the heat transfer fluid circulates through the heat transfer fluid supply system 1.

When the temperature of the heat transfer fluid passing through the body to-be-cooled 20 is increased to be higher than the first temperature, the controller 90 closes the pressure regulating valve 80. Accordingly, the heat transfer fluid that absorbs heat while passing through the body to-be-cooled 20 thermally expands, thereby gradually increasing the inner pressure of the tank 10.

In particular, as the temperature of the heat transfer fluid gradually increases, the volume of the heat transfer fluid gradually increases by thermal expansion, thereby preventing the tank 10 from being damaged by stress due to a sudden change in inner pressure. In addition, by controlling the inner pressure of the tank 10 using the thermal expansion or the thermal contraction of the heat transfer fluid, the noise problem caused by the air purge may be prevented.

When the temperature of the heat transfer fluid passing through the body to-be-cooled 20 additionally increases to be higher than the second temperature, the controller 90 opens the pressurizing pump valve 61. Accordingly, the inside of the tank 10 is maintained in a pressurized state with a predetermined pressure added by the pressurizing pump 60. In this embodiment, 0.5 atmosphere is added by the pressurizing pump 60, and the inner pressure of the tank 10 is maintained at 1.5 atmospheres.

At this time, the pressurizing pump 60 may be provided with a pneumatic regulator 62. The pneumatic regulator 62 regulates the pressure of the dry air provided by the pressurizing pump 60 to the inside of the tank 10 to maintain the inner pressure of the tank 10 at a constant state. The pneumatic regulator 62 may be used in various known devices.

By providing the pneumatic regulator 62, the inner pressure of the tank 10 may be maintained at a constant state with a predetermined pressure added to one atmosphere by the pressurizing pump 60 even if there is thermal expansion of the heat transfer fluid.

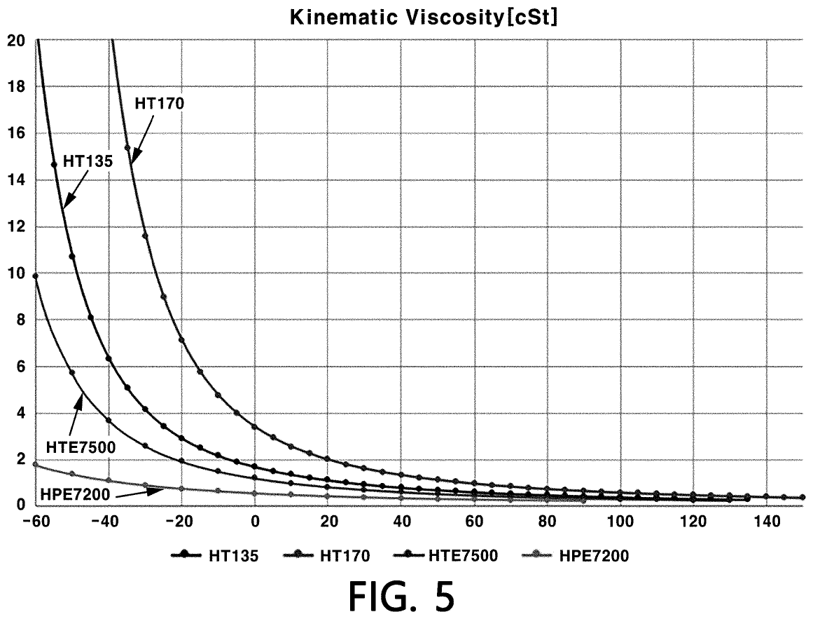

Hereinafter, the effect of the heat transfer fluid supply system 1 according to an embodiment of the present disclosure will be described with reference to FIGS. 5 to 8.

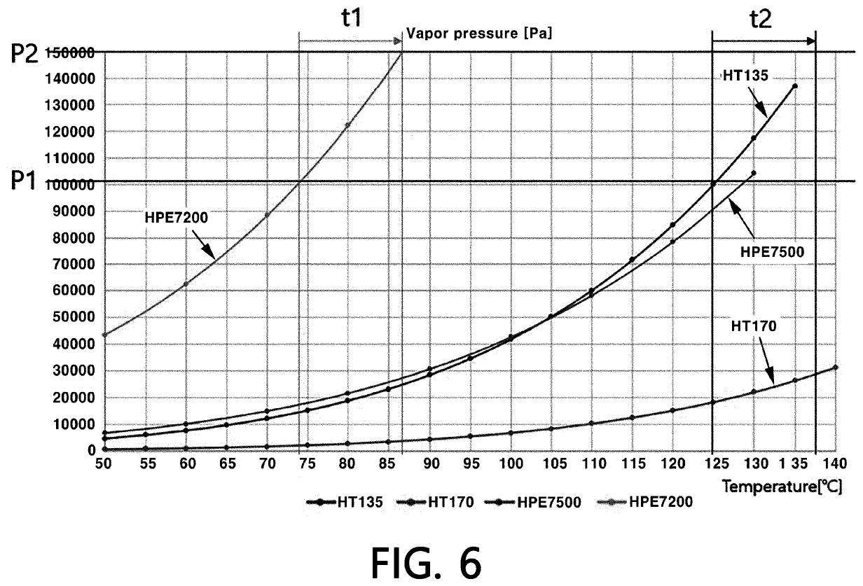

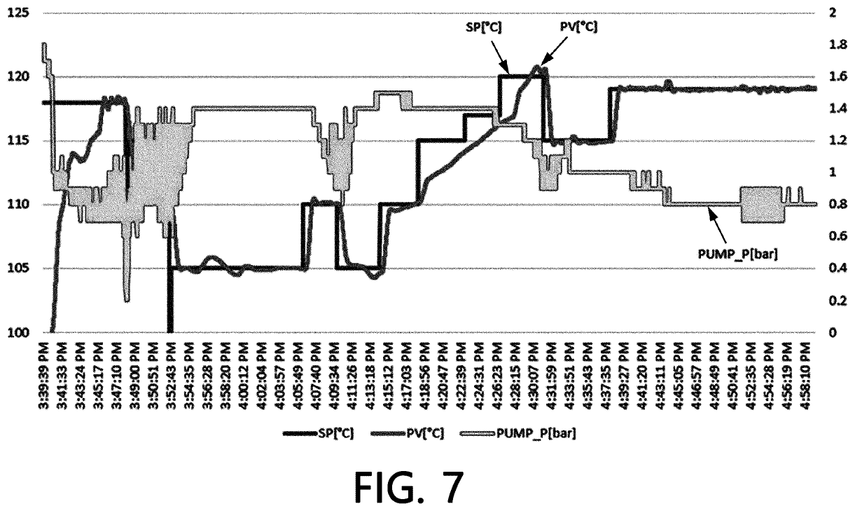

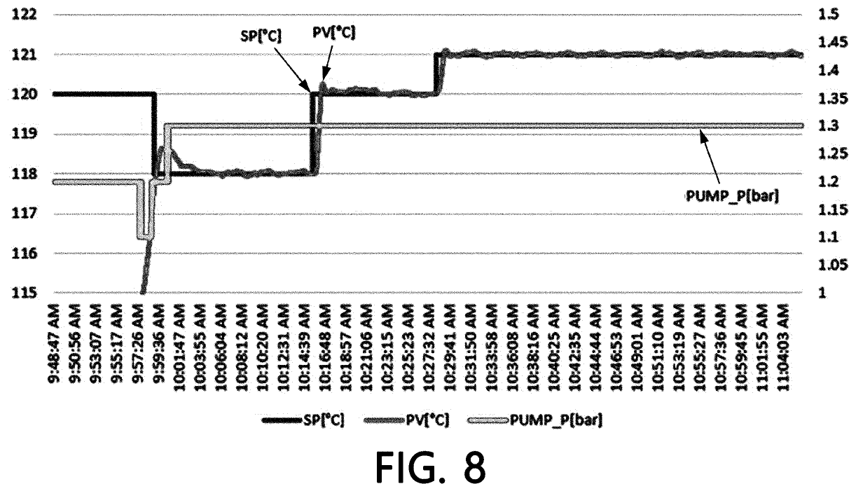

FIG. 5 is a graph showing viscosity according to temperature of the heat transfer fluid used in the heat transfer fluid supply system according to an embodiment of the present disclosure. FIG. 6 is a graph showing pressure according to vaporization point of the heat transfer fluid used in the heat transfer fluid supply system according to an embodiment of the present disclosure. FIG. 7 is a graph showing pressure over time of the heat transfer fluid used in the conventional heat transfer fluid supply system. FIG. 8 is a graph showing pressure over time of the heat transfer fluid used in the heat transfer fluid supply system according to an embodiment of the present disclosure.

As shown in FIG. 5, it may be seen that the viscosity of the heat transfer fluid increases as the temperature decreases regardless of the type of heat transfer fluid. In other words, when the supply flow path L1, the body to-be-cooled 20, and the return flow path L2 are circulated at a low temperature, the pressure applied to the pipe and the pump 40 increases and the pump 40 may be overloaded, and the convective effect of the heat transfer fluid decreases and the heat exchange performance of the heat transfer fluid decreases.

However, in order to prevent this, when a low-viscosity heat transfer fluid is used at low temperature, there is a problem that formation of fluid flow may be restricted due to the low vaporization point.

At this time, as shown in FIG. 6, increasing the pressure of the heat transfer fluid from P1 to P2 increases the vaporization point. More specifically, when the pressure is increased to 0.5 bar, the vaporization point increases by 10 degrees or more.

Accordingly, even when the low-viscosity heat transfer fluid is used at low temperature, stability problems and limitations in fluid fluidity may be reduced. In other words, in the conventional case, as shown in FIG. 7, as the heat transfer fluid is circulated, it may be seen that the fluid flowability is unstable because the target temperature SP and the actual measured temperature PV of the body to-be-cooled are different from each other, and the pressure of the pump PUMP_P does not have a certain value.

On the other hand, in this embodiment, as shown in FIG. 8, the difference between the target temperature SP and the actual measured temperature PV of the body to-be-cooled 20 is small, so that the temperature of the body to-be-cooled 20 may be controlled more precisely, and the pressure of the pump PUMP_P maintains more constant value, so that the fluid flowability is stable.

As described above, the preferred embodiments of the present disclosure were described, and it is apparent to those skilled in the art that the present disclosure can be embodied in other specific forms without departing from the spirit and scope of the present disclosure. Therefore, the above embodiments should be considered as illustrative, not restrictive, and the present disclosure is not limited to the above description, and accordingly, the scope of the appended claims and equivalents thereof may be modified.

### INDUSTRIAL APPLICABILITY

The present disclosure can be applied to an apparatus for inspecting semiconductor devices.

1. A system for supplying heat transfer fluid, comprising:
a body to-be-cooled having a heat transfer flow path through which a heat transfer fluid passes therein;
a tank in which the heat transfer fluid is stored, wherein the heat transfer fluid is stored in a space formed inside the tank;
a supply flow path connecting one side of the heat transfer flow path and the tank;
a return flow path connecting the other side of the heat transfer flow path and the tank; and
a controller that controls an inner pressure of the tank.

2. The system of claim 1, further comprising:
a pressurizing pump supplying dry air to the tank,
wherein the controller is configured to add a predetermined pressure to the inner pressure of the tank using the pressurizing pump.

3. The system of claim 2, further comprising:
a pressurizing pump valve provided in the tank to allow the inner space of the tank and the pressurizing pump to communicate with each other.

4. The system of claim 3, wherein the controller controls the inner pressure of the tank by controlling an opening and closing of the pressurizing pump valve.

5. The system of claim 3, wherein the pressurizing pump constantly provides the predetermined pressure.

6. The system of claim 2, wherein a position where the pressurizing pump is connected to the tank is located above a water level of the heat transfer fluid stored in the tank.

7. The system of claim 2, wherein the predetermined pressure is 0.4 bar or more and 0.6 bar or less.

8. The system of claim 1, further comprising:
a body to-be-cooled heater for heating the body to-be-cooled,
wherein the controller controls a temperature of the body to-be-cooled using the heat transfer fluid and the body to-be-cooled heater.

9. The system of claim 8, further comprising:
a pressure regulating valve provided in the tank to allow the inner space of the tank and the outside of the tank to communicate with each other.

10. The system of claim 9, wherein the controller controls the inner pressure of the tank by controlling an opening and closing of the pressure regulating valve.

11. The system of claim 10, wherein the controller controls the inner pressure added to the tank by thermal expansion of the heat transfer fluid passing through the body to-be-cooled.

12. The system of claim 10, further comprising:
a pressure sensor provided in the tank to measure the inner pressure of the tank, wherein the controller controls the inner pressure of the tank by controlling the opening and closing of the pressure regulating valve through pressure information measured using the pressure sensor.

13. The system of claim 10, further comprising:
a temperature sensor provided in the tank to measure a temperature of the heat transfer fluid stored in the tank,
wherein the controller controls the inner pressure of the tank by controlling the opening and closing of the pressure regulating valve through temperature information measured using the temperature sensor.

14. The system of claim 13, further comprising:
a pressurizing pump supplying dry air to constantly provide a predetermined pressure to the tank, and
a pressurizing pump valve provided in the tank to allow the inner space of the tank and the pressurizing pump to communicate with each other,
wherein the controller controls the inner pressure of the tank by further controlling the opening and closing of the pressurizing pump valve.

15. The system of claim 14, wherein the controller closes the pressurizing pump valve and opens the pressure regulating valve when the temperature information measured using the temperature sensor is less than a first temperature.

16. The system of claim 14, wherein the controller opens the pressurizing pump valve and closes the pressure regulating valve when the temperature information measured using the temperature sensor is equal to or higher than the first temperature such that the inner pressure of the tank gradually increases by thermal expansion of the heat transfer fluid passing through the body to-be-cooled.

17. The system of claim 16, wherein the controller opens the pressurizing pump valve when the temperature information measured using the temperature sensor is greater than or equal to a second temperature that is higher than the first temperature.

18. The system of claim 17, further comprising:
a pneumatic regulator that constantly maintains the inner pressure of the tank in a state in which the inside of the tank is pressurized using the pressurizing pump.

19. The system of claim 1, wherein a position where the supply flow path is connected to the tank is located below the water level of the heat transfer fluid stored inside the tank, and a position where the return flow path is connected to the tank is located below the water level of the heat transfer fluid stored inside the tank.

20. The system of claim 1, further comprising:
a pump connected to the supply flow path or the return flow path to generate a fluid flow such that the heat transfer fluid stored inside the tank returns to the tank via the supply flow path, the body to-be-cooled, and the return flow path in that order; and
a temperature regulator maintaining the temperature of the heat transfer fluid provided to the body to-be-cooled at a predetermined temperature.
